(19) United States
(12) Patent Application Publication
(10) Pub. No.: US 2026/0029577 A1
(43) Pub. Date: Jan. 29, 2026

(54) PHOTONIC CHIP STRUCTURE AND SEMICONDUCTOR PACKAGE INCLUDING THE SAME

(71) Applicant: SAMSUNG ELECTRONICS CO., LTD., Suwon-si (KR)

(72) Inventors: Jung Hua CHANG, Suwon-si (KR); Jing Cheng LIN, Suwon-si (KR)

(73) Assignee: SAMSUNG ELECTRONICS CO., LTD., Suwon-si (KR)

(21) Appl. No.: 19/069,619

(22) Filed: Mar. 4, 2025

(30) Foreign Application Priority Data
Jul. 25, 2024 (KR) 10-2024-0098918

(51) Int. Cl. G02B 6/124; H01L 23/00; H01L 23/31; H01L 23/48; H01L 23/538; H01L 25/16

(52) U.S. Cl. CPC G02B 6/124; H01L 24/16; H01L 25/167; H01L 23/3135; H01L 23/481; H01L 23/5385; H01L 2224/16145

(57) ABSTRACT

A photonic chip structure may include: an electronic integrated circuit chip; a connection terminal connected to the electronic integrated circuit chip; an optical integrated circuit chip under the electronic integrated circuit chip and the connection terminal in a vertical direction and including a photonic integrated circuit (PIC) connection pad and a first PIC insulating layer on the PIC connection pad, the PIC connection pad connected to the connection terminal; and an optical block spaced apart from the electronic integrated circuit chip in a horizontal direction and configured to provide a path for optical signals to the optical integrated circuit chip, wherein the first PIC insulating layer includes a first cavity, and the optical block is in the first cavity.

### CROSS-REFERENCE TO RELATED APPLICATION

This application is based on and claims priority under 35 U.S.C. § 119 to Korean Patent Application No. 10-2024-0098918, filed on Jul. 25, 2024, in the Korean Intellectual Property Office, the disclosure of which is incorporated by reference herein in its entirety.

### BACKGROUND

### 1. Field

Embodiments of the present disclosure relate to a photonic chip structure and a semiconductor package including the photonic chip structure, and more particularly, to a photonic chip structure including an optical integrated circuit chip and a semiconductor package including the photonic chip structure.

### 2. Brief Description of Background Art

The advantages of semiconductor packages have been increasingly used to improve the functionality of electronic devices and to integrate the components thereof. A semiconductor package may allow various integrated circuits such as memory chips or logic chips to be mounted on a package substrate. Recently, in an environment where data traffic has increased in data centers and communication infrastructures, research has continued on semiconductor packages including optical integrated circuits.

### SUMMARY

Problems solved by embodiments of the present disclosure are not limited to the problems mentioned above, and other problems not mentioned herein that are solved by embodiments of the present disclosure will be clearly understood by those of ordinary skill in the art from the following description.

According to some embodiments of the present disclosure, a photonic chip structure may be provided and include: an electronic integrated circuit chip; a connection terminal connected to the electronic integrated circuit chip; an optical integrated circuit chip under the electronic integrated circuit chip and the connection terminal in a vertical direction and including a photonic integrated circuit (PIC) connection pad and a first PIC insulating layer on the PIC connection pad, the PIC connection pad connected to the connection terminal; and an optical block spaced apart from the electronic integrated circuit chip in a horizontal direction and configured to provide a path for optical signals to the optical integrated circuit chip, wherein the first PIC insulating layer includes a first cavity, and the optical block is in the first cavity.

According to some embodiments of the present disclosure, a photonic chip structure may be provided and include: an electronic integrated circuit chip; a connection terminal connected to the electronic integrated circuit chip; an optical integrated circuit chip under the electronic integrated circuit chip and the connection terminal in a vertical direction and including a through electrode and an interlayer insulating layer on at least a portion of the through electrode, the through electrode connected to the connection terminal; an optical block spaced apart from the electronic integrated circuit chip in a horizontal direction and configured to provide a path for optical signals to the optical integrated circuit chip; and an adhesive layer directly contacting the optical block and the interlayer insulating layer.

According to some embodiments of the present disclosure, a semiconductor package may be provided and include: a package substrate; an interposer above the package substrate; a memory chip structure above the interposer; a non-memory chip structure above the interposer and spaced apart from the memory chip structure in a horizontal direction; and a photonic chip structure spaced apart from the non-memory chip structure in the horizontal direction with the non-memory chip structure therebetween, wherein the photonic chip structure includes: an electronic integrated circuit chip; a connection terminal connected to the electronic integrated circuit chip; an optical integrated circuit chip under the electronic integrated circuit chip and the connection terminal in a vertical direction and including a photonic integrated circuit (PIC) connection pad and a PIC insulating layer on the PIC connection pad, the PIC connection pad electrically connected to the connection terminal; and an optical block spaced apart from the electronic integrated circuit chip in the horizontal direction and configured to provide a path for optical signals to the optical integrated circuit chip, and wherein the PIC insulating layer includes a cavity, and the optical block is in the cavity.

According to embodiments of the present disclosure, a photonic chip structure with improved coupling efficiency and a semiconductor package including the photonic chip structure are provided.

### BRIEF DESCRIPTION OF DRAWINGS

Embodiments will be more clearly understood from the following detailed description taken in conjunction with the accompanying drawings in which:

FIG. 1 is a cross-sectional view of a semiconductor package according to an embodiment;

FIG. 2 is a cross-sectional view of an embodiment of a photonic chip structure illustrated in FIG. 1;

FIG. 3 is an enlarged view of a region AX1 of FIG. 2;

FIG. 4 is a cross-sectional view of a photonic chip structure according to an embodiment and is an enlarged view corresponding to FIG. 3;

FIG. 5 is a cross-sectional view of a photonic chip structure according to an embodiment and is an enlarged view corresponding to FIG. 3; and

FIGS. 6 to 17 are cross-sectional views for describing a process of manufacturing a photonic chip structure according to an embodiment.

### DETAILED DESCRIPTION

Terms used in this specification are for the purpose of describing particular example embodiments only and are not intended to be limiting of the present disclosure. In this specification, singular forms are intended to include plural forms as well, unless the context clearly indicates otherwise. The terms “comprises” (or “includes”) and/or “comprising” (or “including”) when used in this specification, specify the presence of stated features, steps, operations, elements, and/or components, but do not preclude the presence or addition of one or more other features, steps, operations, elements, components, and/or groups thereof.

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

Hereinafter, non-limiting example embodiments of the present disclosure will be described in detail with reference to the accompanying drawings. Herein, like reference numerals will denote like elements, and redundant descriptions thereof may be omitted for conciseness.

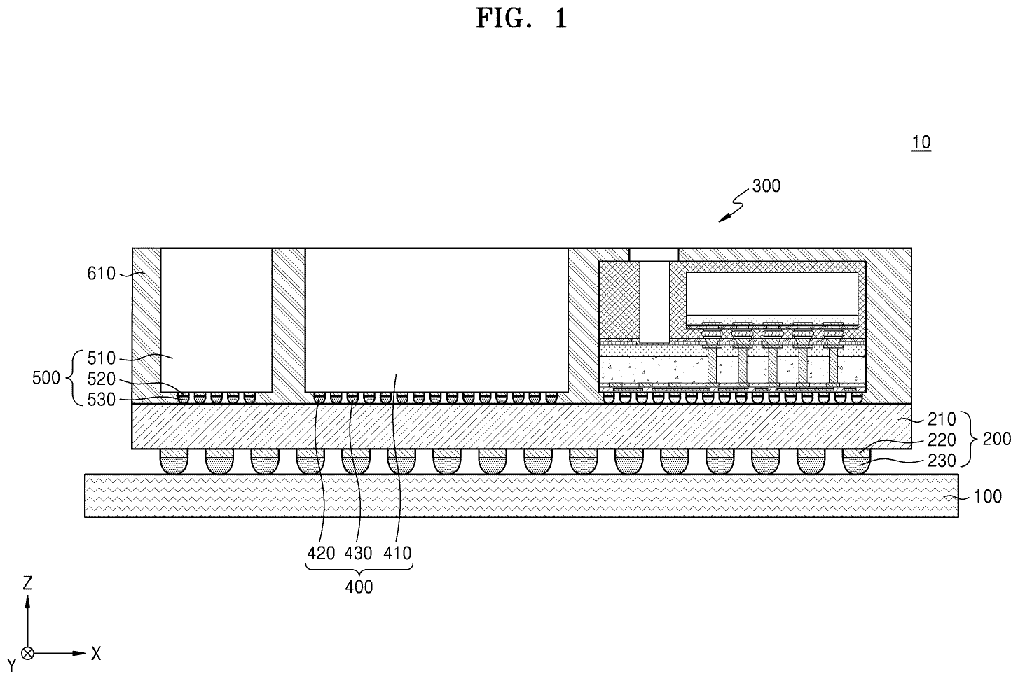

FIG. 1 is a cross-sectional view of a semiconductor package 10 according to an embodiment.

Referring to FIG. 1, the semiconductor package 10 according to an embodiment may include a package substrate 100, an interposer 200, a photonic chip structure 300, a first chip structure 400, a second chip structure 500, and a package molding layer 610.

The photonic chip structure 300 will be described later in detail, and the other components will be described first. Hereinafter, unless otherwise defined, a direction parallel to the upper surface of the package substrate 100 is defined as a first horizontal direction (X direction), a direction perpendicular to the upper surface of the package substrate 100 is defined as a vertical direction (Z direction), and a direction perpendicular to the first horizontal direction (X direction) and the vertical direction (Z direction) is defined as a second horizontal direction (Y direction). A direction corresponding to the first horizontal direction (X direction) and/or the second horizontal direction (Y direction) is defined as a horizontal direction.

The package substrate 100 may include, for example, a printed circuit board (PCB). The package substrate 100 may include an upper surface with an area sufficient to accommodate the interposer 200. The package substrate 100 may include a core insulating layer including at least one material selected from among phenol resin, epoxy resin, and polyimide. For example, the core insulating layer may include at least one material selected from among polyimide, Flame Retardant 4 (FR-4), tetrafunctional epoxy, polyphenylene ether, epoxy/polyphenylene oxide, bismaleimide triazine (BT), thermount, cyanate ester, and liquid crystal polymer.

According to an embodiment, the interposer 200 may include an interposer substrate 210, an interposer pad 220, and an interposer bump 230.

In an embodiment, the interposer 200 may be arranged between the package substrate 100 and a plurality of chip structures (e.g., the photonic chip structure 300, the first chip structure 400, and the second chip structure 500) in the vertical direction (Z direction) and may be configured to electrically connect the plurality of chip structures to each other. That is, the photonic chip structure 300, the first chip structure 400, and the second chip structure 500 may transmit/receive electrical signals to/from each other through the interposer 200.

For example, the material of the interposer substrate 210 may include silicon (Si). However, without being limited thereto, the interposer substrate 210 may include a semiconductor element such as germanium and may include a semiconductor compound such as silicon carbide (SiC), gallium arsenide (GaAs), indium arsenide (InAs), and indium phosphide (InP).

The interposer pad 220 may be located on the lower surface of the interposer substrate 210 to provide a terminal on which the interposer bump 230 is to be arranged. According to embodiments, a plurality of through electrodes or a plurality of line patterns may be formed in the interposer substrate 210. The plurality of through electrodes and the plurality of line patterns may be connected to the interposer pad 220.

In an embodiment, the material of the interposer pad 220 may include aluminum (Al). However, without being limited thereto, the material of the interposer pad 220 may include a metal such as nickel (Ni), copper (Cu), gold (Au), silver (Ag), tungsten (W), titanium (Ti), tantalum (Ta), indium (In), molybdenum (Mo), manganese (Mn), cobalt (Co), tin (Sn), magnesium (Mg), rhenium (Re), beryllium (Be), gallium (Ga), and ruthenium (Ru), or any alloy thereof.

The interposer bump 230 may include a terminal for electrically connecting the interposer 200 and the package substrate 100 arranged under the interposer 200. In an embodiment, the interposer bump 230 may include a solder of a metal material including at least one from among tin (Sn), silver (Ag), copper (Cu), and aluminum (Al).

The photonic chip structure 300, the first chip structure 400, and the second chip structure 500 may be mounted on the upper surface of the interposer 200. According to an embodiment, the photonic chip structure 300 may be located at an outer portion of the upper surface of the interposer 200.

According to an embodiment, the first chip structure 400 may be arranged adjacent to a center portion of the upper surface of the interposer substrate 210, and the second chip structure 500 may be arranged apart from the photonic chip structure 300 in the first horizontal direction (X direction) with the first chip structure 400 therebetween. In this case, the spacing distance between the first chip structure 400 and the second chip structure 500 in the first horizontal direction (X direction) and the spacing distance between the first chip structure 400 and the photonic chip structure 300 in the first horizontal direction (X direction) may be substantially the same as each other. However, embodiments of the present disclosure are not limited thereto, and according to embodiments, the spacing distance between the first chip structure 400 and the second chip structure 500 and the spacing distance between the first chip structure 400 and the photonic chip structure 300 may be different from each other.

The first chip structure 400 may include a first chip body 410, a first chip pad 420, and a first chip bump 430. Herein, the first chip structure 400 may include a non-memory chip structure including a non-memory device. The first chip body 410 may include, for example, silicon. Alternatively, the first chip body 410 may include a semiconductor element such as germanium or a compound semiconductor such as silicon carbide (SiC), gallium arsenide (GaAs), indium arsenide (InAs), and indium phosphide (InP). Alternatively, the first chip body 410 may have a silicon-on-insulator (SOI) structure. For example, the first chip body 410 may include a buried oxide (BOX) layer. The first chip body 410 may include a conductive area such as, for example, a well doped with dopants or a structure doped with dopants. Also, the first chip body 410 may have various device isolation structures such as a shallow trench isolation (STI) structure.

The first chip structure 400 may include, for example, a system-on-chip, a central processing unit (CPU) chip, a graphic processing unit (GPU) chip, or an application processor (AP) chip. The first chip structure 400 may execute applications supported by the semiconductor package 10 by using a memory device included in the second chip structure 500. For example, the first chip structure 400 may include at least one processor from among a central processing unit (CPU), an application processor (AP), a graphic processing unit (GPU), a neural processing unit (NPU), a tensor processing unit (TPU), a vision processing unit (VPU), an image signal processor (ISP), and a digital signal processor (DSP) to execute specialized operations.

According to an embodiment, a plurality of first chip pads 420 may be arranged in a lateral direction (X direction and/or Y direction) on the lower surface of the first chip body 410. According to an embodiment, the upper surface of the first chip pad 420 may be on a same plane as the lower surface of the first chip body 410, and the first chip pad 420 may contact the first chip bump 430. Through the interposer 200, the first chip pad 420 may receive an electrical signal from the second chip structure 500 or the photonic chip structure 300, or may transmit an electrical signal to the second chip structure 500 or the photonic chip structure 300.

The first chip pad 420 may include, for example, a conductive material including copper (Cu), gold (Au), silver (Ag), nickel (Ni), tungsten (W), aluminum (Al), or any combination thereof. In some embodiments, the first chip pad 420 may further include a barrier material to prevent the conductive material from diffusing outside the first chip pad 420. The barrier material may include, for example, titanium (Ti), tantalum (Ta), titanium nitride (TiN), tantalum nitride (TaN), or any combination thereof.

According to an embodiment, a plurality of first chip bumps 430 may be attached to the plurality of first chip pads 420 that are on the first chip body 410. The first chip bump 430 may include, for example, a conductive material including tin (Sn), lead (Pb), silver (Ag), copper (Cu), or any combination thereof. The first chip bump 430 may be formed by using, for example, a solder ball. The first chip bump 430 may connect the first chip structure 400 to the interposer 200.

The second chip structure 500 may include a second chip body 510, a second chip pad 520, and a second chip bump 530. Herein, the second chip structure 500 may include a memory chip structure including a memory device. The second chip body 510 may include, for example, silicon. Alternatively, the second chip body 510 may include a semiconductor element such as germanium or a compound semiconductor such as silicon carbide (SiC), gallium arsenide (GaAs), indium arsenide (InAs), and indium phosphide (InP). Alternatively, the second chip body 510 may have a silicon-on-insulator (SOI) structure. For example, the second chip body 510 may include a buried oxide (BOX) layer. The second chip body 510 may include a conductive area such as, for example, a well doped with dopants or a structure doped with dopants. Also, the second chip body 510 may have various device isolation structures such as a shallow trench isolation (STI) structure.

The second chip structure 500 may include, for example, a dynamic random access memory (DRAM), a static random access memory (SRAM), a flash memory, an electrically erasable and programmable read-only memory (EEPROM), a phase-change random access memory (PRAM), a magnetic random access memory (MRAM), or a resistive random access memory (RRAM). According to an embodiment, the second chip structure 500 may include a memory cell chip including a cell of high bandwidth memory (HBM) DRAM.

According to an embodiment, a plurality of second chip pads 520 may be arranged in the lateral direction (X direction and/or Y direction) on the lower surface of the second chip body 510. According to an embodiment, the upper surface of the second chip pad 520 may be on a same plane as the lower surface of the second chip body 510, and the second chip pad 520 may contact the second chip bump 530. Through the interposer 200, the second chip pad 520 may receive an electrical signal from the first chip structure 400 or the photonic chip structure 300, or may transmit an electrical signal to the first chip structure 400 or the photonic chip structure 300.

The second chip pad 520 may include, for example, a conductive material including copper (Cu), gold (Au), silver (Ag), nickel (Ni), tungsten (W), aluminum (Al), or any combination thereof. In some embodiments, the second chip pad 520 may further include a barrier material to prevent the conductive material from diffusing outside the second chip pad 520. The barrier material may include, for example, titanium (Ti), tantalum (Ta), titanium nitride (TiN), tantalum nitride (TaN), or any combination thereof.

According to an embodiment, a plurality of second chip bumps 530 may be attached to the plurality of second chip pads 520 that are on the second chip body 510. The second chip bump 530 may include, for example, a conductive material including tin (Sn), lead (Pb), silver (Ag), copper (Cu), or any combination thereof. The second chip bump 530 may be formed by using, for example, a solder ball. The second chip bump 530 may connect the second chip structure 500 to the interposer 200.

According to an embodiment, the package molding layer 610 may surround (e.g., seal) the first chip structure 400, the second chip structure 500, and the photonic chip structure 300 on the upper surface of the interposer 200. Also, the package molding layer 610 may cover the side surfaces of the first chip structure 400, the second chip structure 500, and the photonic chip structure 300. By sealing the devices arranged in the semiconductor package 10 with a single package molding layer 610, the warpage of the semiconductor package 10 may be reduced.

The package molding layer 610 may include, for example, a thermosetting resin such as an epoxy resin, a thermoplastic resin such as a polyimide, or a resin including an inorganic filler therein, such as, ABF, FR-4, BT, resin, or the like. Also, a molding material such as epoxy mold compounds (EMC) or a photosensitive material such as photo-imageable-epoxy (PIE) may be used.

According to an embodiment of the present disclosure, a thickness of the optical integrated circuit chip 310a may be about 10 micrometers to about 200 micrometers in the vertical direction (Z direction), and/or a thickness of the electronic integrated circuit chip 340 may be about 550 micrometers to about 750 micrometers in the vertical direction (Z direction).

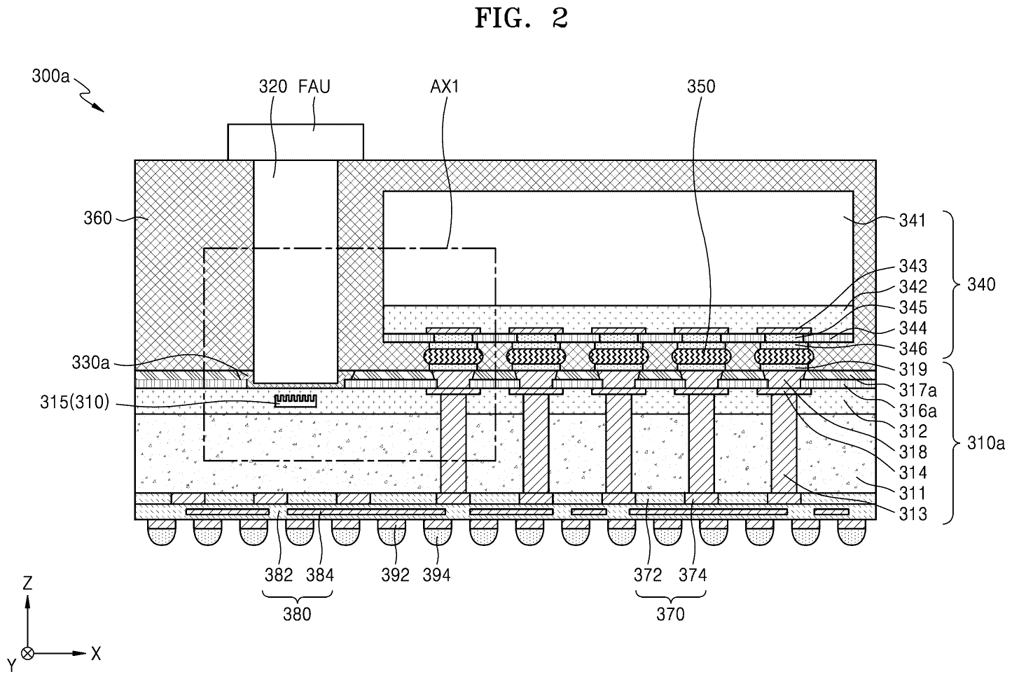

FIG. 2 is a cross-sectional view of an embodiment of the photonic chip structure 300 illustrated in FIG. 1.

Referring to FIG. 2, a photonic chip structure 300a may include an optical integrated circuit chip 310a, an optical block 320, an adhesive layer 330a, an electronic integrated circuit chip 340, a connection terminal 350, a chip molding layer 360, a lower connection layer 370, a redistribution structure 380, a photonic chip pad 392, and a photonic chip bump 394. The photonic chip structure 300a illustrated in FIG. 2 may be an example of the photonic chip structure 300 illustrated in FIG. 1.

According to an embodiment, the optical integrated circuit chip 310a may include a first substrate 311, a first interlayer insulating layer 312, a through electrode 313, a photonic integrated circuit (PIC) lower pad 314, a grating coupler 315, a first PIC insulating layer 316a, a second PIC insulating layer 317a, a PIC connection pad 318, and a PIC upper pad 319.

The first substrate 311 may include an upper surface facing the electronic integrated circuit chip 340 and a lower surface opposite thereto. The lower surface of the first substrate 311 may be a surface facing the redistribution structure 380. The through electrode 313 may extend from the upper surface to the lower surface of the first substrate 311. In this case, the lower end of the through electrode 313 may be physically and electrically connected to a lower pad 374 of the lower connection layer 370, and the upper end of the through electrode 313 may be physically and electrically connected to the PIC lower pad 314.

According to an embodiment, the first interlayer insulating layer 312 may extend along the upper surface of the first substrate 311. The first interlayer insulating layer 312 may have a certain thickness and may be formed along the upper surface of the first substrate 311, and the first interlayer insulating layer 312 may include an inorganic insulating layer such as silicon oxide (SiO) or silicon nitride (SiN). Alternatively, the first interlayer insulating layer 312 may include a polymer material. Alternatively, the first interlayer insulating layer 312 may include an insulating polymer or a photosensitive polymer (e.g., a photoimageable dielectric (PID)). For example, the photosensitive polymer may include at least one from among photosensitive polyimide, polybenzoxazole (PBO), a phenol-based polymer, and a benzocyclobutene-based polymer. The first interlayer insulating layer 312 may include two or more insulating materials that are stacked on each other.

According to an embodiment, the through electrode 313 may be formed to pass through the first substrate 311 and the first interlayer insulating layer 312. Particularly, the through electrode 313 may extend from the lower surface of the first substrate 311 to the PIC lower pad 314. The through electrode 313 may provide an electrical connection path from the lower connection layer 370 to the PIC lower pad 314.

According to an embodiment, the PIC lower pad 314 may be arranged in the upper surface of the first interlayer insulating layer 312. The upper surface of the PIC lower pad 314 may be located on the same plane as the upper surface of the first interlayer insulating layer 312. The lower surface of the PIC lower pad 314 may be located to contact the upper surface of the through electrode 313. In this case, the width of the PIC lower pad 314 in the lateral direction (X direction and/or Y direction) may be greater than the width of the through electrode 313 in the lateral direction (X direction and/or Y direction).

The through electrode 313 and the PIC lower pad 314 may include, for example, a conductive material including copper (Cu), gold (Au), silver (Ag), nickel (Ni), tungsten (W), aluminum (Al), or any combination thereof. In some embodiments, the through electrode 313 and the PIC lower pad 314 may further include a barrier material to prevent the conductive material from diffusing outside the through electrode 313 and the PIC lower pad 314. The barrier material may include, for example, titanium (Ti), tantalum (Ta), titanium nitride (TiN), tantalum nitride (TaN), or any combination thereof.

According to an embodiment, the grating coupler 315 may be buried in the first interlayer insulating layer 312. The grating coupler 315 may be configured to couple an optical signal incident to the optical block 320 through an optical fiber unit FAU. Particularly, an optical signal arriving at the grating coupler 315 through the optical block 320 may be coupled to another waveguide. The grating coupler 315 may include a semiconductor material, such as silicon (Si).

According to an embodiment, the first PIC insulating layer 316a may have a certain thickness and may extend along the upper surface of the first interlayer insulating layer 312, and the first PIC insulating layer 316a may include an inorganic insulating layer such as silicon oxide (SiO) or silicon nitride (SiN). Alternatively, the first PIC insulating layer 316a may include a polymer material. Alternatively, the first PIC insulating layer 316a may include an insulating polymer or a photosensitive polymer (e.g., a photoimageable dielectric (PID)). For example, the photosensitive polymer may include at least one from among photosensitive polyimide, polybenzoxazole (PBO), a phenol-based polymer, and a benzocyclobutene-based polymer. The first PIC insulating layer 316a may include two or more insulating materials that are stacked on each other.

In a horizontal view (e.g., the view shown in FIG. 2), the outer perimeter of the first PIC insulating layer 316a may correspond to the outer perimeter of the first interlayer insulating layer 312. For example, side surfaces of the first PIC insulating layer 316a and the first interlayer insulating layer 312 may be coplanar with respect to each other.

According to an embodiment, the second PIC insulating layer 317a may have a certain thickness and may extend along the upper surface of the first PIC insulating layer 316a, and the second PIC insulating layer 317a may include an inorganic insulating layer such as silicon oxide (SiO) or silicon nitride (S/N). Alternatively, the second PIC insulating layer 317a may include a polymer material. Alternatively, the second PIC insulating layer 317a may include an insulating polymer or a photosensitive polymer (e.g., a photoimageable dielectric (PID)). For example, the photosensitive polymer may include at least one from among photosensitive polyimide, polybenzoxazole (PBO), a phenol-based polymer, and a benzocyclobutene-based polymer. The second PIC insulating layer 317a may include two or more insulating materials that are stacked on each other.

In a horizontal view (e.g., the view shown in FIG. 2), the outer perimeter of the second PIC insulating layer 317a may correspond to the outer perimeter of the first interlayer insulating layer 312. For example, side surfaces of the second PIC insulating layer 317a and the first interlayer insulating layer 312 may be coplanar with respect to each other. The second PIC insulating layer 317a may be arranged between the first PIC insulating layer 316a and the chip molding layer 360.

According to an embodiment, the PIC connection pad 318 may be buried in the first PIC insulating layer 316a and the second PIC insulating layer 317a. The PIC connection pad 318 may have a two-stage structure with different diameters. In this case, a portion of the PIC connection pad 318 with a smaller diameter may be buried in the first PIC insulating layer 316a, and a portion of the PIC connection pad 318 with a greater diameter may be buried in the second PIC insulating layer 317a. The PIC connection pad 318 may be arranged between the PIC lower pad 314 and the PIC upper pad 319 to electrically connect the PIC lower pad 314 and the PIC upper pad 319 to each other.

According to an embodiment, the PIC upper pad 319 may be arranged over the PIC connection pad 318. In this case, the PIC upper pad 319 may be arranged over the second PIC insulating layer 317a to physically and electrically connect the connection terminal 350 and the PIC connection pad 318 to each other. The lower surface of the PIC upper pad 319 may be on a same plane as the upper surface of the second PIC insulating layer 317a.

The PIC connection pad 318 and the PIC upper pad 319 may include, for example, a conductive material including copper (Cu), gold (Au), silver (Ag), nickel (Ni), tungsten (W), aluminum (Al), or any combination thereof. In some embodiments, the PIC connection pad 318 and the PIC upper pad 319 may further include a barrier material to prevent the conductive material from diffusing outside the PIC connection pad 318 and the PIC upper pad 319. The barrier material may include, for example, titanium (Ti), tantalum (Ta), titanium nitride (TiN), tantalum nitride (TaN), or any combination thereof.

According to an embodiment, the optical fiber unit FAU may be arranged outside the chip molding layer 360 and may be connected to the optical block 320. The optical fiber unit FAU may include a unit including a plurality of optical fibers. An optical signal from the outside may enter the optical block 320 of the photonic chip structure 300a through the optical fiber of the optical fiber unit FAU. The optical fiber unit FAU may include a plurality of optical fibers, and in some embodiments, the optical fibers may input/output optical signals with different wavelengths. In some embodiments, the optical fiber may input/output an optical signal with multiple wavelengths. For example, the optical signal emitted by the optical fiber may have a plurality of peak wavelengths.

According to an embodiment, the optical block 320 may pass through the chip molding layer 360. One end of the optical block 320 may be connected to the optical fiber unit FAU, and the other end opposite to the one end may contact the adhesive layer 330a. The optical integrated circuit chip 310a may receive an optical signal from the optical block 320 through the grating coupler 315 or transmit an optical signal to the optical block 320 through the grating coupler 315. The grating coupler 315 may control the direction of an optical signal incident through the optical block 320. That is, the optical signal incident through the optical block 320 may travel along the waveguide by being changed in its propagation direction by the grating coupler 315.

The optical block 320 may be located over the optical integrated circuit chip 310a and may pass through the chip molding layer 360. The optical block 320 may be located over the optical integrated circuit chip 310a to be spaced apart from the electronic integrated circuit chip 340 in the first horizontal direction (X direction). The optical block 320 may be located over the grating coupler 315 and the waveguide of the optical integrated circuit chip 310a.

An optical path through which an external optical signal is transmitted to the optical integrated circuit chip 310a may be formed in the optical block 320. Most of the optical path through which an external optical signal is transmitted to the optical integrated circuit chip 310a may be formed in the optical block 320. For example, the photonic chip structure 300a may be configured such that more than 98% of the optical path is formed in the optical block 320.

The optical block 320 may include a main body having a certain refractive index. For example, the material of the main body may include silicon, glass, or polymer. Because the main body of the optical block 320 has a certain refractive index, the light reflection occurring between two materials having different refractive indexes may be reduced while the optical signal passes through the main body. Because 98% or more of the optical path is formed in the optical block 320, the optical loss due to light reflection may be reduced.

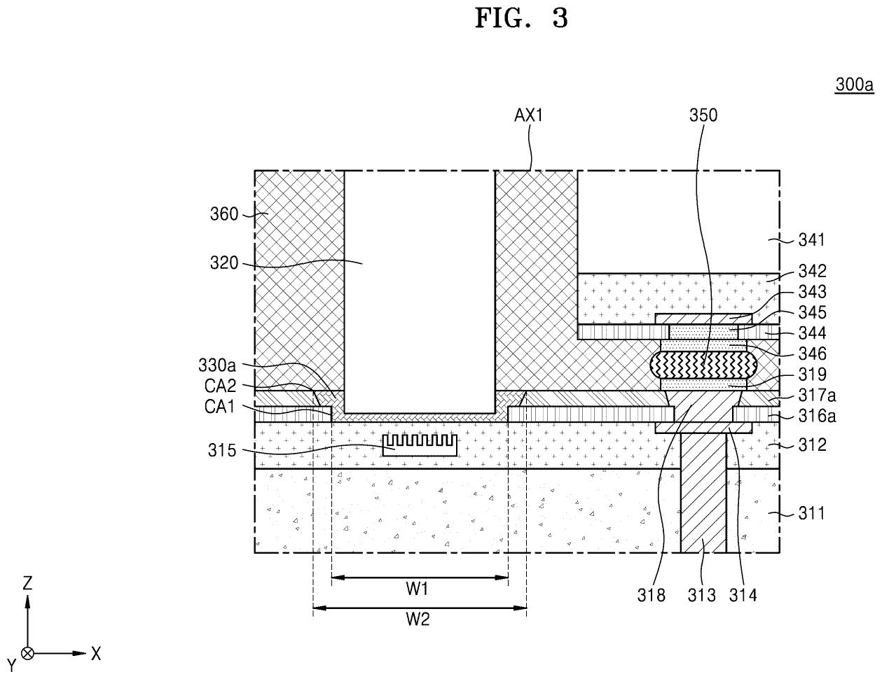

According to an embodiment, the adhesive layer 330a may be arranged between the optical block 320 and the first interlayer insulating layer 312 to attach the optical block 320 to the first interlayer insulating layer 312. The first interlayer insulating layer 312 will be described below in detail with reference to FIG. 3.

According to an embodiment, the electronic integrated circuit chip 340 may be mounted over the optical integrated circuit chip 310a. The electronic integrated circuit chip 340 may be arranged over the optical integrated circuit chip 310a to be spaced apart from the optical block 320 in the first horizontal direction (X direction). The electronic integrated circuit chip 340 may include a second substrate 341, a second interlayer insulating layer 342, an electronic integrated circuit (EIC) upper pad 343, an EIC insulating layer 344, an EIC connection pad 345, and an EIC lower pad 346.

The second substrate 341 of the electronic integrated circuit chip 340 may include an active surface and an inactive surface opposite thereto.

The second substrate 341 may include a semiconductor material, such as silicon (Si). Also, the second substrate 341 may include a semiconductor material such as germanium (Ge).

In some embodiments, the electronic integrated circuit chip 340 may include a plurality of separate devices used to interface with the optical integrated circuit chip 310a. The plurality of separate devices of the electronic integrated circuit chip 340 may be located on the active surface of the second substrate 341. Herein, the active surface of the second substrate 341 may be the lower surface of the second substrate 341. For example, the electronic integrated circuit chip 340 may include complementary metal-oxide semiconductor (CMOS) drivers, transimpedance amplifiers, and the like to perform a function such as controlling high-frequency signaling of the optical integrated circuit chip 310a.

According to an embodiment, the second interlayer insulating layer 342 may extend along the lower surface of the second substrate 341. The second interlayer insulating layer 342 may have a certain thickness and may be formed along the lower surface of the second substrate 341, and the second interlayer insulating layer 342 may include an inorganic insulating layer such as silicon oxide (SiO) or silicon nitride (SiN). Alternatively, the second interlayer insulating layer 342 may include a polymer material. Alternatively, the second interlayer insulating layer 342 may include an insulating polymer or a photosensitive polymer (photoimageable dielectric (PID)). For example, the photosensitive polymer may include at least one from among photosensitive polyimide, polybenzoxazole (PBO), a phenol-based polymer, and a benzocyclobutene-based polymer. The second interlayer insulating layer 342 may include two or more insulating materials that are stacked on each other.

According to an embodiment, the EIC upper pad 343 may be arranged over the EIC connection pad 345. In this case, the lower surface of the EIC upper pad 343 may be on a same plane as the lower surface of the second interlayer insulating layer 342.

According to an embodiment, the EIC insulating layer 344 may have a certain thickness and may extend along the lower surface of the second interlayer insulating layer 342, and the EIC insulating layer 344 may include an inorganic insulating layer such as silicon oxide (SiO) or silicon nitride (SiN). Alternatively, the EIC insulating layer 344 may include a polymer material. Alternatively, the EIC insulating layer 344 may include an insulating polymer or a photosensitive polymer (e.g., a photoimageable dielectric (PID)). For example, the photosensitive polymer may include at least one from among photosensitive polyimide, polybenzoxazole (PBO), a phenol-based polymer, and a benzocyclobutene-based polymer. The EIC insulating layer 344 may include two or more insulating materials that are stacked on each other.

In a horizontal view (e.g., the view shown in FIG. 2), the outer perimeter of the EIC insulating layer 344 may correspond to the outer perimeter of the second interlayer insulating layer 342. For example, side surfaces of the EIC insulating layer 344 and the second interlayer insulating layer 342 may be coplanar with respect to each other. The EIC insulating layer 344 may be arranged between the second interlayer insulating layer 342 and the chip molding layer 360.

According to an embodiment, the EIC connection pad 345 may be buried in the EIC insulating layer 344. Unlike the PIC connection pad 318 with a two-stage structure, the EIC connection pad 345 may have a diameter in a certain vertical direction (Z direction). However, this is merely an example, and the shape of the EIC connection pad 345 may vary according to embodiments. The EIC connection pad 345 may be arranged between the EIC lower pad 346 and the EIC upper pad 343 to electrically connect the EIC lower pad 346 and the EIC upper pad 343 to each other.

According to an embodiment, the EIC lower pad 346 may be arranged under the EIC connection pad 345. In this case, the EIC lower pad 346 may be arranged on the lower surface of the EIC insulating layer 344 to physically and electrically connect the EIC connection pad 345 and the connection terminal 350 to each other. The upper surface of the EIC lower pad 346 may be on a same plane as the lower surface of the EIC insulating layer 344.

The EIC upper pad 343, the EIC connection pad 345, and the EIC lower pad 346 may include, for example, a conductive material including copper (Cu), gold (Au), silver (Ag), nickel (Ni), tungsten (W), aluminum (Al), or any combination thereof. In some embodiments, the EIC upper pad 343, the EIC connection pad 345, and the EIC lower pad 346 may further include a barrier material to prevent the conductive material from diffusing outside the EIC upper pad 343, the EIC connection pad 345, and the EIC lower pad 346. The barrier material may include, for example, titanium (Ti), tantalum (Ta), titanium nitride (TiN), tantalum nitride (TaN), or any combination thereof.

According to an embodiment, the connection terminal 350 may be bonded to the EIC lower pad 346 and the PIC upper pad 319. The connection terminal 350 may include, for example, a conductive material including tin (Sn), lead (Pb), silver (Ag), copper (Cu), or any combination thereof. The connection terminal 350 may be formed by using, for example, a solder ball. The connection terminal 350 may electrically connect the electronic integrated circuit chip 340 to the optical integrated circuit chip 310a.

The chip molding layer 360 may surround (e.g., seal) the optical block 320 and the electronic integrated circuit chip 340 on the upper surface of the second PIC insulating layer 317a. The chip molding layer 360 may cover the upper surface of the second PIC insulating layer 317a and surround the side surfaces of the optical block 320 and the electronic integrated circuit chip 340. Also, according to an embodiment, the vertical level of the upper surface of the chip molding layer 360 may be located higher than the vertical level of the upper surface of the second substrate 341. Thus, the chip molding layer 360 may cover the upper surface of the second substrate 341. Also, the chip molding layer 360 may fill the space between a plurality of connection terminals 350. However, according to another embodiment, the vertical level of the upper surface of the chip molding layer 360 may be the same as the vertical level of the upper surface of the second substrate 341. In this case, the chip molding layer 360 may not cover the upper surface of the second substrate 341 and may cover the side surface of the second substrate 341.

The chip molding layer 360 may include, for example, a thermosetting resin such as an epoxy resin, a thermoplastic resin such as a polyimide, or a resin including an inorganic filler therein, such as, ABF, FR-4, BT, resin, or the like. Also, a molding material such as EMC or a photosensitive material such as PIE may be used.

According to an embodiment, the lower connection layer 370 may be arranged under the optical integrated circuit chip 310a in the vertical direction (Z direction). The lower connection layer 370 may provide a space in which the optical integrated circuit chip 310a is mounted and may provide an electrical connection path between the optical integrated circuit chip 310a and the redistribution structure 380.

The lower connection layer 370 may include a lower insulating layer 372 and a lower pad 374. The lower insulating layer 372 may have a certain thickness and may extend along the lower surface of the first substrate 311, and the lower insulating layer 372 may include an inorganic insulating layer such as silicon oxide (SiO) or silicon nitride (SiN). Alternatively, the lower insulating layer 372 may include a polymer material. Alternatively, the lower insulating layer 372 may include an insulating polymer or a photosensitive polymer (e.g., a photoimageable dielectric (PID)). For example, the photosensitive polymer may include at least one from among photosensitive polyimide, polybenzoxazole (PBO), a phenol-based polymer, and a benzocyclobutene-based polymer. The lower insulating layer 372 may include two or more insulating materials that are stacked on each other.

In a horizontal view (e.g., the view shown in FIG. 2), the outer perimeter of the lower insulating layer 372 may correspond to the outer perimeter of the first substrate 311. For example, side surfaces of the lower insulating layer 372 and the first substrate 311 may be coplanar with respect to each other.

The side surface of the lower pad 374 may be surrounded by the lower insulating layer 372.

The lower pad 374 may be arranged in the lower insulating layer 372. In this case, the lower pad 374 may be exposed from the upper surface of the lower insulating layer 372 and also from the lower surface of the lower insulating layer 372. A plurality of lower pads 374 may function as a connection terminal between the through electrode 313 and the redistribution structure 380. The lower pad 374 may include a metal material such as, for example, an alloy including at least one metal or two or more metals among copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), and carbon (C).

According to an embodiment, the redistribution structure 380 may be arranged under the lower connection layer 370 in the vertical direction (Z direction). The redistribution structure 380 may extend along the lower surface of the lower connection layer 370 and may provide an electrical connection path between the photonic chip bump 394 and the lower connection layer 370.

The redistribution structure 380 may include a redistribution insulating layer 382 and a redistribution pattern layer 384. The redistribution insulating layer 382 may have a certain thickness and may extend along the lower surface of the lower insulating layer 372 of the lower connection layer 370, and the redistribution insulating layer 382 may include an inorganic insulating layer such as silicon oxide (SiO) or silicon nitride (SiN). Alternatively, the redistribution insulating layer 382 may include a polymer material. Alternatively, the redistribution insulating layer 382 may include an insulating polymer or a photosensitive polymer (e.g., a photoimageable dielectric (PID)). For example, the photosensitive polymer may include at least one from among photosensitive polyimide, polybenzoxazole (PBO), a phenol-based polymer, and a benzocyclobutene-based polymer. The redistribution insulating layer 382 may include two or more insulating materials that are stacked on each other.

The redistribution pattern layer 384 may be arranged in the redistribution insulating layer 382. A plurality of redistribution pattern layers 384 may be provided, and the plurality of redistribution pattern layers 384 may be arranged at different vertical levels in the redistribution insulating layer 382. The redistribution pattern layer 384 may redistribute the photonic chip pad 392 and the lower pad 374. The redistribution pattern layer 384 may perform various functions according to the configuration of the pattern. For example, the redistribution pattern layer 384 may include a ground pattern, a power pattern, a signal pattern, and the like. The signal pattern may include various signals such as a data signal, excluding the ground pattern, the power pattern, and the like. Here, the pattern may include a line and a pad. Also, a plurality of redistribution pattern layers 384 may be arranged at different vertical levels, and redistribution vias may be connected between the redistribution pattern layers 384 arranged at different vertical levels.

The redistribution pattern layer 384 may include a conductive material including copper (Cu), gold (Au), silver (Ag), nickel (Ni), tungsten (W), aluminum (Al), or any combination thereof. In some embodiments, the redistribution pattern layer 384 may further include a barrier material to prevent the conductive material from diffusing outside the redistribution pattern layer 384. The barrier material may include, for example, titanium (Ti), tantalum (Ta), titanium nitride (TiN), tantalum nitride (TaN), or any combination thereof.

According to an embodiment, a plurality of the photonic chip pad 392 may be arranged with respect to each other in the lateral direction (X direction and/or Y direction) on the lower surface of the redistribution structure 380. The photonic chip pad 392 may be located on the lower surface of the redistribution structure 380 to provide a terminal at which the photonic chip bump 394 is to be arranged. According to embodiments, a plurality of through electrodes or a plurality of line patterns may be formed in the interposer substrate 210 (see FIG. 1). The plurality of through electrodes and the plurality of line patterns may be connected to the photonic chip pad 392.

In an embodiment, the material of the photonic chip pad 392 may include aluminum (Al). However, without being limited thereto, the material of the photonic chip pad 392 may include a metal such as nickel (Ni), copper (Cu), gold (Au), silver (Ag), tungsten (W), titanium (Ti), tantalum (Ta), indium (In), molybdenum (Mo), manganese (Mn), cobalt (Co), tin (Sn), magnesium (Mg), rhenium (Re), beryllium (Be), gallium (Ga), and ruthenium (Ru), or any alloy thereof.

The photonic chip bump 394 may be a terminal for electrical connection with the interposer 200. In an embodiment, the photonic chip bump 394 may include a solder of a metal material including at least one from among tin (Sn), silver (Ag), copper (Cu), and aluminum (Al).

According to an embodiment, the semiconductor package 10 of FIG. 1 may communicate with an external device through the photonic chip structure 300a by using an optical signal. The photonic chip structure 300a may receive an optical signal from an external device, convert the received optical signal into an electrical signal, and input the electrical signal into the first chip structure 400 and the second chip structure 500 through the interposer 200.

The optical integrated circuit chip 310a may convert an optical signal received through the optical block 320 into an electrical signal by using an optical component and convert the electrical signal into an optical signal. The optical component may include a photodetector, a photodiode, or a modulator.

In the process of inputting an optical signal into the photonic chip structure 300a, the photodetector may detect the optical signal input into the optical integrated circuit chip 310a. The optical integrated circuit chip 310a may detect an optical signal input through the photodetector and convert the optical signal into an electrical signal.

FIG. 3 is an enlarged view of a region AX1 of FIG. 2.

According to an embodiment, the optical block 320 may face the first interlayer insulating layer 312 of the optical integrated circuit chip 310a with the adhesive layer 330a therebetween. Simultaneously, the optical block 320 may overlap the grating coupler 315 in the first interlayer insulating layer 312 in the vertical direction (Z direction). According to an embodiment, the first PIC insulating layer 316a may include a first cavity CA1, and the second PIC insulating layer 317a may include a second cavity CA2. The first cavity CA1 may have a first width W1, and the second cavity CA2 may have a second width W2 greater than the first width W1. The first cavity CA1 of the first PIC insulating layer 316a may completely overlap with the second cavity CA2 of the second PIC insulating layer 317a in the vertical direction (Z direction).

According to an embodiment, the optical block 320 may be accommodated in the first cavity CA1 of the first PIC insulating layer 316a and the second cavity CA2 of the second PIC insulating layer 317a. Also, the adhesive layer 330a may be configured to adhere and support the optical block 320 such that the optical block 320 may be accommodated in the first cavity CA1 and the second cavity CA2. The adhesive layer 330a may contact the side surface and the lower surface of a lower end portion of the optical block 320 and may contact the side surface of the first PIC insulating layer 316a in the first cavity CA1 and contact the side surface of the second PIC insulating layer 317a in the second cavity CA2. Also, the adhesive layer 330a may contact the upper surface of the first interlayer insulating layer 312.

Because the first cavity CA1 and the second cavity CA2 are formed in the first PIC insulating layer 316a and the second PIC insulating layer 317a and the adhesive layer 330a is located in the first cavity CA1 and the second cavity CA2, only the adhesive layer 330a may be arranged between the optical block 320 and the first interlayer insulating layer 312 in which the grating coupler 315 is buried. Thus, because the configuration and structures intervening between the optical block 320 and the grating coupler 315 are simplified, the efficiency of the optical signal may be improved.

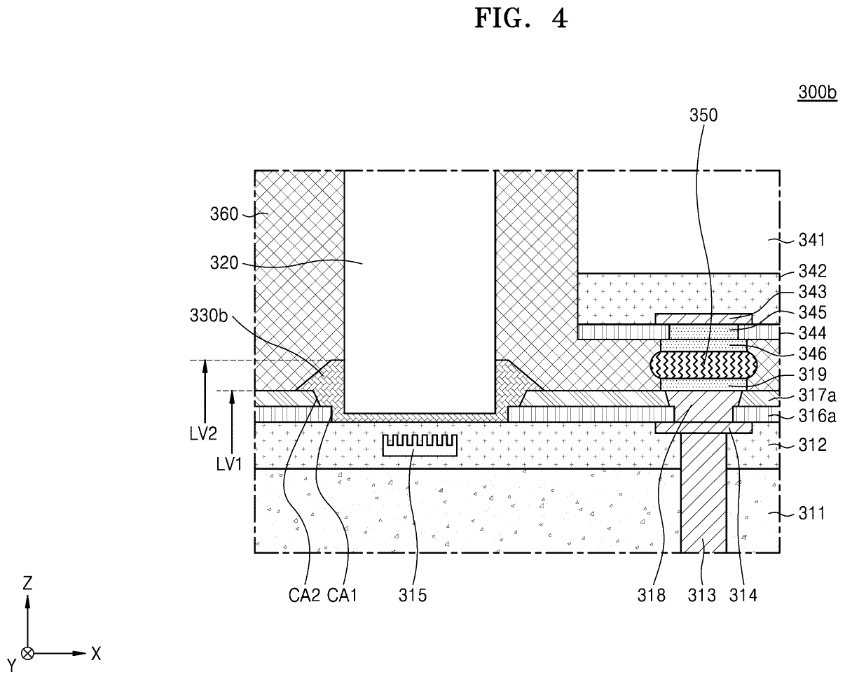

FIG. 4 is a cross-sectional view of a photonic chip structure 300b according to an embodiment and is an enlarged view corresponding to FIG. 3.

The photonic chip structure 300b illustrated in FIG. 4 may be substantially the same as or similar to the photonic chip structure 300a illustrated in FIG. 3, except that the shape of an adhesive layer 330b is different therefrom. Thus, redundant description of the components described above with reference to FIG. 2 and FIG. 3 may be omitted or simplified for conciseness.

Referring to FIG. 4, the optical block 320 may face the first interlayer insulating layer 312 of the optical integrated circuit chip 310 with the adhesive layer 330b therebetween. Simultaneously, the optical block 320 may overlap the grating coupler 315 in the first interlayer insulating layer 312 in the vertical direction (Z direction).

According to an embodiment, unlike the adhesive layer 330a illustrated in FIG. 3, the adhesive layer 330b illustrated in FIG. 4 may have an upper surface covering a portion of the upper surface of the second PIC insulating layer 317a. Also, a vertical level LV2 of the uppermost surface of the adhesive layer 330b in the vertical direction (Z direction) may be higher than a vertical level LV1 of the uppermost surface of the second PIC insulating layer 317a in the vertical direction (Z direction).

When the adhesive layer 330b covering the optical block 320 contacts a portion of the upper surface of the second PIC insulating layer 317a due to the vertical level of the uppermost surface of the adhesive layer 330b increases, the contact area between the adhesive layer 330b and the optical block 320 may increase and thus the optical block 320 may be more stably attached to the optical integrated circuit chip 310.

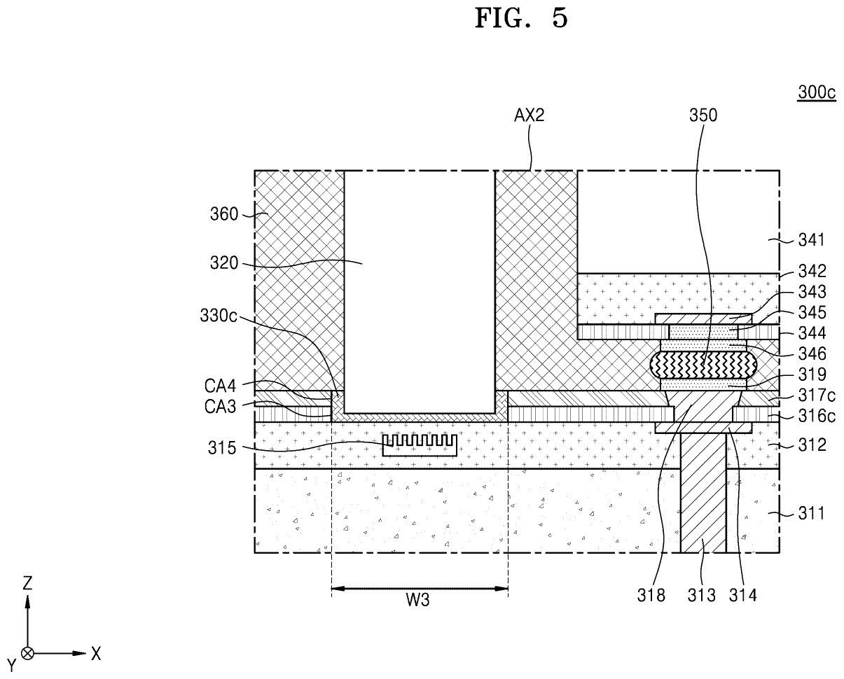

FIG. 5 is a cross-sectional view of a photonic chip structure 300c according to an embodiment and is an enlarged view corresponding to FIG. 3.

The photonic chip structure 300c illustrated in FIG. 5 may be substantially the same as or similar to the photonic chip structure 300a illustrated in FIG. 3, except that the shapes of a third cavity CA3 of the first PIC insulating layer 316c and a fourth cavity CA4 of the second PIC insulating layer 317c are different therefrom and the shape of an adhesive layer 330c is different therefrom. Thus, redundant description of the components described above with reference to FIG. 2 and FIG. 3 may be omitted or simplified for conciseness.

According to an embodiment, the optical block 320 may face the first interlayer insulating layer 312 of the optical integrated circuit chip 310 with the adhesive layer 330c therebetween. Simultaneously, the optical block 320 may overlap the grating coupler 315 in the first interlayer insulating layer 312 in the vertical direction (Z direction). According to an embodiment, the first PIC insulating layer 316c may include a third cavity CA3, and the second PIC insulating layer 317c may include a fourth cavity CA4. Each of the third cavity CA3 and the fourth cavity CA4 may have a third width W3 in the first horizontal direction (X direction). In this case, when the shapes of the first cavity CA1 and the second cavity CA2 are circular, the widths of the third cavity CA3 and the fourth cavity CA4 in the lateral direction (X direction and/or Y direction) may be the third width W3.

According to an embodiment, the side surface of the first PIC insulating layer 316c in the third cavity CA3 and the side surface of the second PIC insulating layer 317c in the fourth cavity CA4 may overlap with each other such as to be coplanar.

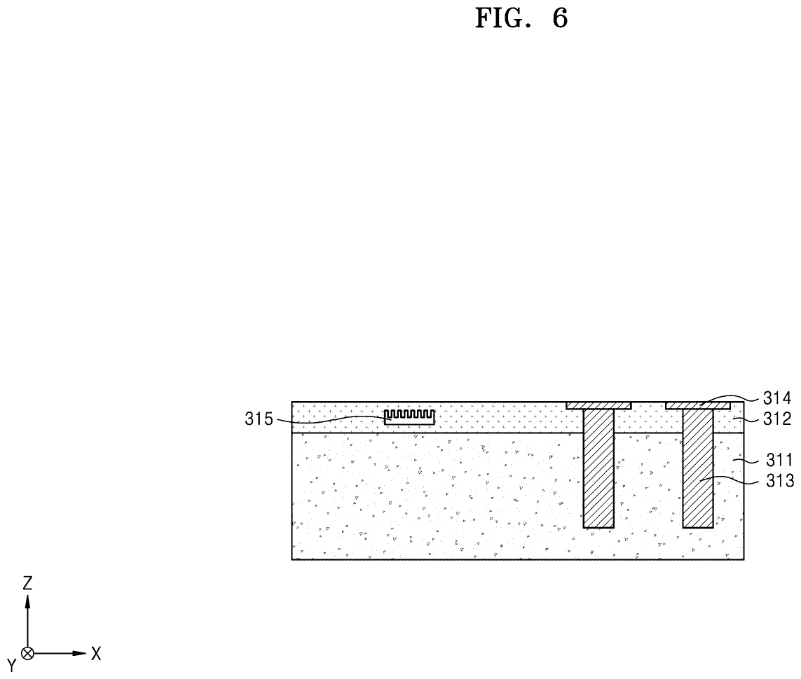

FIGS. 6 to 17 are cross-sectional views for describing a process of manufacturing a photonic chip structure according to an embodiment.

Referring to FIG. 6, a first interlayer insulating layer 312 may be formed over a first substrate 311 by using a deposition process. The deposition process may include at least one from among a physical vapor deposition (PVD) process, a chemical vapor deposition (CVD) process, and an atomic layer deposition (ALD) process. The chemical vapor deposition process may include a deposition process such as a plasma enhanced chemical vapor deposition (PVD) or a high density plasma chemical vapor deposition (HDPCVD).

While depositing the first interlayer insulating layer 312, a grating coupler 315 may be formed through a photolithography process on a semiconductor material. Also, after forming a hole in the first substrate 311 and the first interlayer insulating layer 312, the hole may be filled with a conductive material to form a through electrode 313 and a PIC lower pad 314.

The conductive material may include a metal such as nickel (Ni), copper (Cu), gold (Au), silver (Ag), tungsten (W), titanium (Ti), tantalum (Ta), indium (In), molybdenum (Mo), manganese (Mn), cobalt (Co), tin (Sn), magnesium (Mg), rhenium (Re), beryllium (Be), gallium (Ga), and ruthenium (Ru), or any alloy thereof.

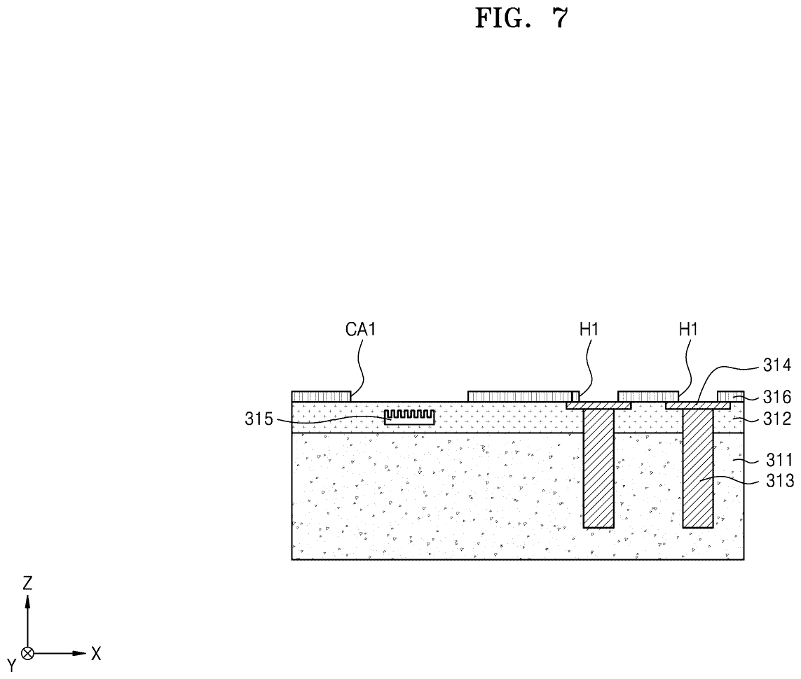

Referring to FIG. 7, a first PIC insulating layer 316 may be formed over the first interlayer insulating layer 312. In this case, the first PIC insulating layer 316 may include a plurality of first holes H1 and a first cavity CA1. The plurality of first holes H1 may be located to overlap the through electrodes 313 and the PIC lower pads 314 in the vertical direction (Z direction). Each of the upper surfaces of a plurality of PIC lower pads 314 may be exposed by the first holes H1.

A process of depositing the first PIC insulating layer 316 may be a process similar to a process of depositing the first interlayer insulating layer 312. A process of forming the plurality of first holes H1 and the first cavity CA1 in the first PIC insulating layer 316 may be an etching process.

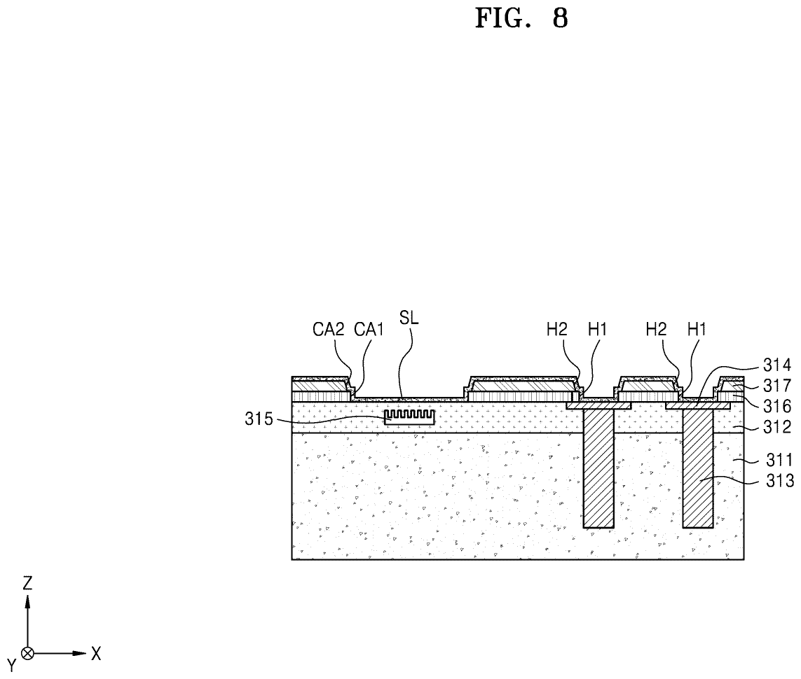

Referring to FIG. 8, a process of depositing a second PIC insulating layer 317 on the first PIC insulating layer 316 may be performed. In this case, a process of depositing the second PIC insulating layer 317 may be a process similar to a process of depositing the first interlayer insulating layer 312. After depositing the second PIC insulating layer 317, a plurality of second holes H2 and a second cavity CA2 may be formed in the second PIC insulating layer 317. In this case, a process of forming the plurality of second holes H2 and the second cavity CA2 in the second PIC insulating layer 317 may be an etching process.

Each of the plurality of second holes H2 may overlap the first holes H1 in the vertical direction (Z direction). In this case, the width of the second hole H2 in the lateral direction (X direction and/or Y direction) may be greater than the width of the first hole H1 in the lateral direction (X direction and/or Y direction). Also, the second cavity CA2 may overlap the first cavity CA1 in the vertical direction (Z direction). In this case, the width of the second cavity CA2 in the lateral direction (X direction and/or Y direction) may be greater than the width of the first cavity CA1 in the lateral direction (X direction and/or Y direction).

After forming the plurality of second holes H2 and the second cavity CA2 in the second PIC insulating layer 317, a seed layer SL may be formed over the second PIC insulating layer 317. In this case, the seed layer SL may be conformally formed on the upper surface of the second PIC insulating layer 317 through a deposition process. Also, the seed layer SL may cover the side surface of the second PIC insulating layer 317 in the second cavity CA2 and the plurality of second holes H2 of the second PIC insulating layer 317, and may cover the side surface of the first PIC insulating layer 316 in the first cavity CA₁ and the plurality of first holes H1 of the first PIC insulating layer 316. In addition, the seed layer SL may cover the upper surface of the first interlayer insulating layer 312 in the first cavity CA1 of the first PIC insulating layer 316 and may cover the upper surface of the PIC lower pads 314 in the plurality of first holes H1 of the first PIC insulating layer 316.

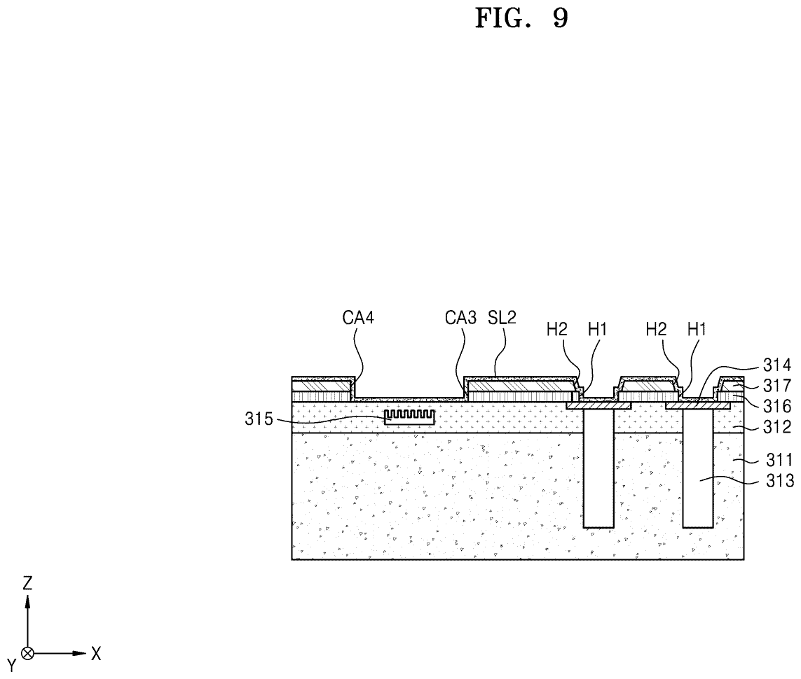

FIG. 9 is a cross-sectional view illustrating a process of manufacturing a photonic chip structure according to an embodiment. FIG. 9 is a cross-sectional view corresponding to the manufacturing process illustrated in FIG. 8 and illustrates a process of manufacturing the photonic chip structure 300c illustrated in FIG. 5. Hereinafter, differences from FIG. 8 will be mainly described.

Referring to FIG. 9, after depositing a first PIC insulating layer 316, a third cavity CA3 may be formed in the first PIC insulating layer 316, and after depositing a second PIC insulating layer 317, a fourth cavity CA4 may be formed therein. In this case, a process of forming the third cavity CA3 in the first PIC insulating layer 316 and a process of forming the fourth cavity CA4 in the second PIC insulating layer 317 may be an etching process. The third cavity CA3 and the fourth cavity CA4 may have the same diameter as each other, and the side surface of the second PIC insulating layer 317 in the fourth cavity CA4 may be on a same plane as the side surface of the first PIC insulating layer 316 in the third cavity CA3.

A method of forming the plurality of second holes H2 and the plurality of first holes H1 may be similar to that described above with reference to FIG. 8, and thus redundant descriptions thereof may be omitted for conciseness.

After forming the plurality of second holes H2 and the fourth cavity CA4 in the second PIC insulating layer 317, a seed layer SL2 may be formed over the second PIC insulating layer 317. In this case, the seed layer SL2 may be conformally formed on the upper surface of the second PIC insulating layer 317 through a deposition process. Also, the seed layer SL2 may cover the side surface of the second PIC insulating layer 317 in the fourth cavity CA4 and the plurality of second holes H2 of the second PIC insulating layer 317, and may cover the side surface of the first PIC insulating layer 316 in the third cavity CA3 and the plurality of first holes H1 of the first PIC insulating layer 316. In addition, the seed layer SL2 may cover the upper surface of the first interlayer insulating layer 312 in the third cavity CA3 of the first PIC insulating layer 316 and may cover the upper surface of the PIC lower pad 314 in the plurality of first holes H1 of the first PIC insulating layer 316.

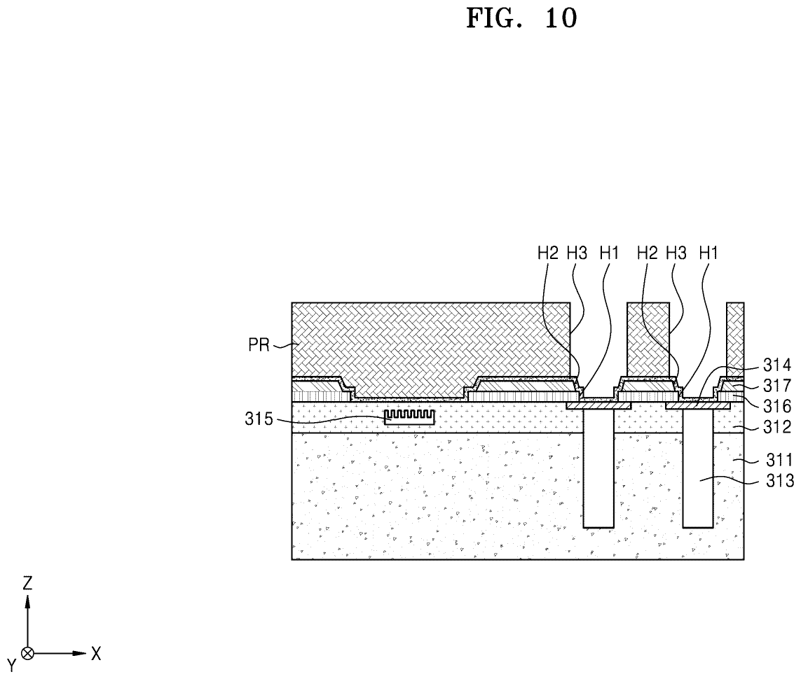

Referring to FIG. 10, a photoresist layer PR may be formed on the seed layer SL (or the seed layer SL2). The photoresist layer PR may be formed through a layer application process such as a spin coating process, a dip coating process, or a spray coating process. In some embodiments, the photoresist layer PR may be formed after a baking process or a curing process is performed on a preliminary photoresist layer formed through the layer application process. In an embodiment, the photoresist layer PR may include a photosensitive material.

Thereafter, an exposure process may be performed by irradiating light on the photoresist layer PR. The exposure process may be performed by arranging an exposure mask on the photoresist layer PR and irradiating light through an opening included in the exposure mask. In some embodiments, the light used in the exposure process may include extreme ultraviolet (EUV) light, but embodiments of the present disclosure are not limited thereto, and the light may include light from a light source such as ArF, KrF, or electron beam.

A development process may be performed on an exposure portion of the photoresist layer PR to form a third hole H3. In some embodiments, the development process may use an aqueous solution such as alcohol or tetramethyl-ammonium-hydroxide (TMAH); however, embodiments of the present disclosure are not limited thereto. When the third hole H3 is formed in the photoresist layer PR, the seed layer SL (or the seed layer SL2) may be exposed by the third hole H3.

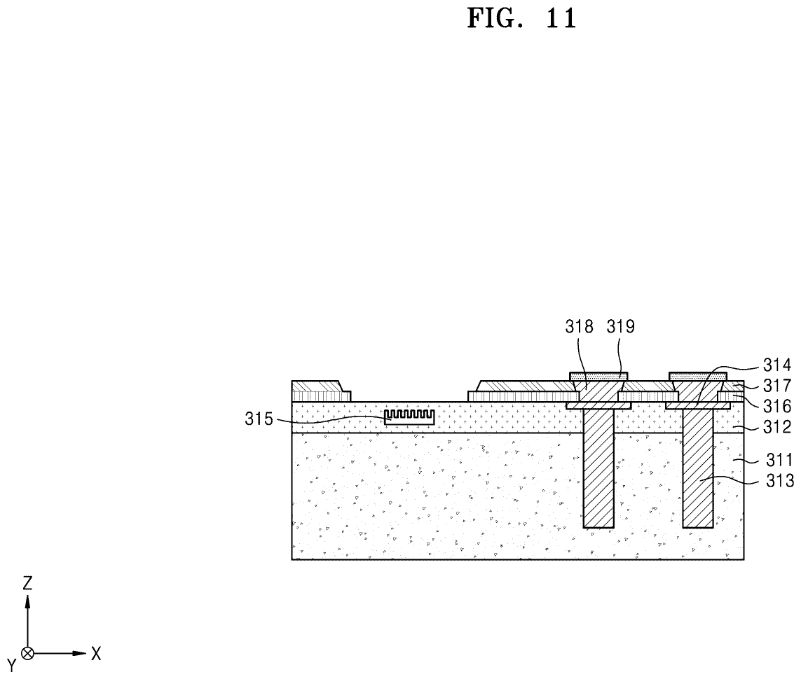

Referring to FIG. 11, after the seed layer SL arranged in the first hole H1, the second hole H2, and the third hole H3, the first hole H1 and the second hole H2 may be filled with a conductive material to form a PIC connection pad 318. After the PIC connection pad 318 is formed, a portion of the third hole H3 may be filled with a conductive material to form a PIC upper pad 319. The lower surface of the PIC upper pad 319 may contact the upper surface of the PIC connection pad 318. In this case, because the width of the PIC upper pad 319 in the lateral direction (X direction and/or Y direction) may be greater than the greatest width of the PIC connection pad 318 in the lateral direction (X direction and/or Y direction), the upper surface of the PIC connection pad 318 may be completely covered by the PIC upper pad 319.

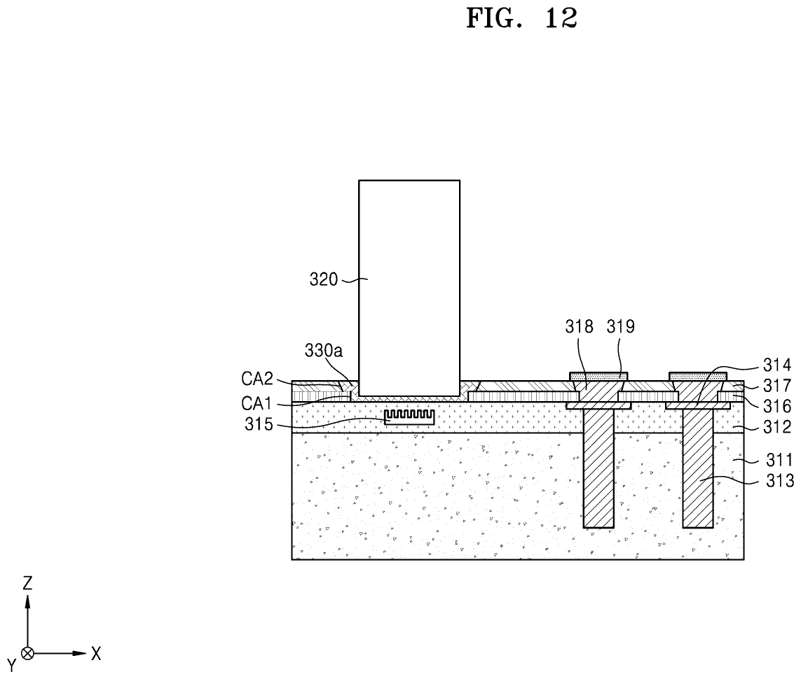

Referring to FIG. 12, after applying an adhesive layer 330a in the first cavity CA1 of the first PIC insulating layer 316 and the second cavity CA2 of the second PIC insulating layer 317, an optical block 320 may be adhered onto the adhesive layer 330a. In this case, the adhesive layer 330a may cover the side surface of the first PIC insulating layer 316 and the upper surface of the first interlayer insulating layer 312 in the first cavity. Also, the adhesive layer 330a may cover the side surface of the second PIC insulating layer 317 in the second cavity CA2.

After applying the adhesive layer 330a, the optical block 320 may be adhered onto the adhesive layer 330a. In this case, the lowermost portion of the optical block 320 may dig into the adhesive layer 330a, and the side surface and lower surface of the lower end portion of the optical block 320 may contact the adhesive layer 330a.

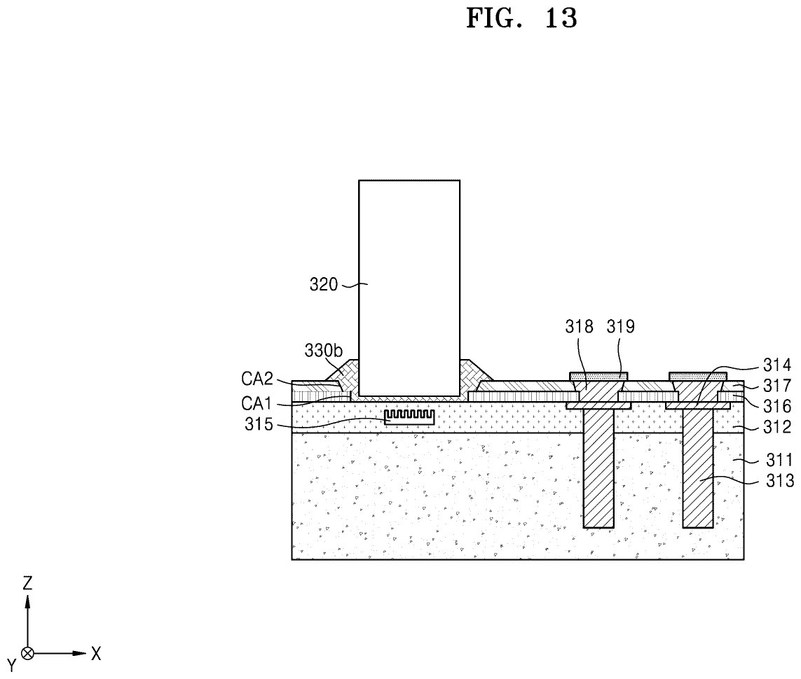

FIG. 13 is a cross-sectional view illustrating a process of manufacturing a photonic chip structure according to an embodiment. FIG. 13 is a cross-sectional view corresponding to the manufacturing process illustrated in FIG. 12 and illustrates a process of manufacturing the photonic chip structure 300b illustrated in FIG. 4. Hereinafter, differences from FIG. 12 will be mainly described.

In the case where a large amount of adhesive layer is applied to the first cavity CA1 of the first PIC insulating layer 316 and the second cavity CA2 of the second PIC insulating layer 317, a significant amount of adhesive layer 330b may overflow from the second cavity CA2 in the process of bonding the optical block 320 to the adhesive layer 330b. In this case, portions of the adhesive layer 330b ejected from the second cavity CA2 may cover a portion of the upper surface of the second PIC insulating layer 317. In this case, the vertical level of the uppermost surface of the adhesive layer 330b may be higher than the vertical level of the uppermost surface of the second PIC insulating layer 317.

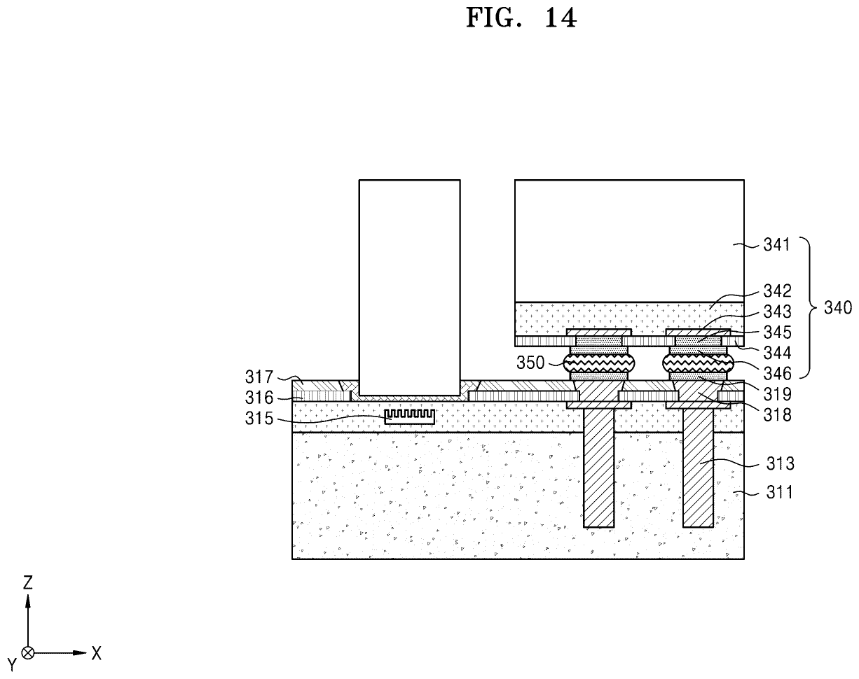

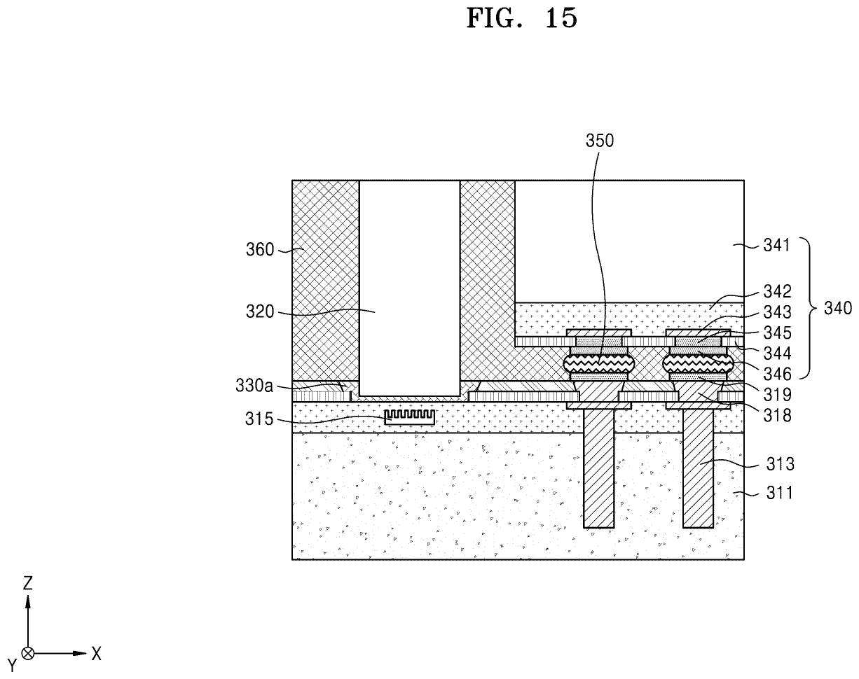

Referring to FIGS. 14 and 15, thereafter, an electronic integrated circuit chip 340 may be mounted on the second PIC insulating layer 317. In the process of mounting the electronic integrated circuit chip 340, a connection terminal 350 of the electronic integrated circuit chip 340 may be bonded to the PIC upper pad 319.

After the connection terminal 350 of the electronic integrated circuit chip 340 is bonded to the PIC upper pad 319, a chip molding layer 360 may be formed. For example, an insulating material may be applied on the upper surface of the second PIC insulating layer 317 to bury the electronic integrated circuit chip 340 and the optical block 320, and the insulating material may be cured. In this case, the insulating material may include, for example, an epoxy mold compound material. After applying the insulating material, the upper end portion of the insulating material and the upper end portion of the electronic integrated circuit chip 340 may be removed through a planarization process according to some embodiments. By removing the upper end portion of the insulating material, the chip molding layer 360 may be completed.

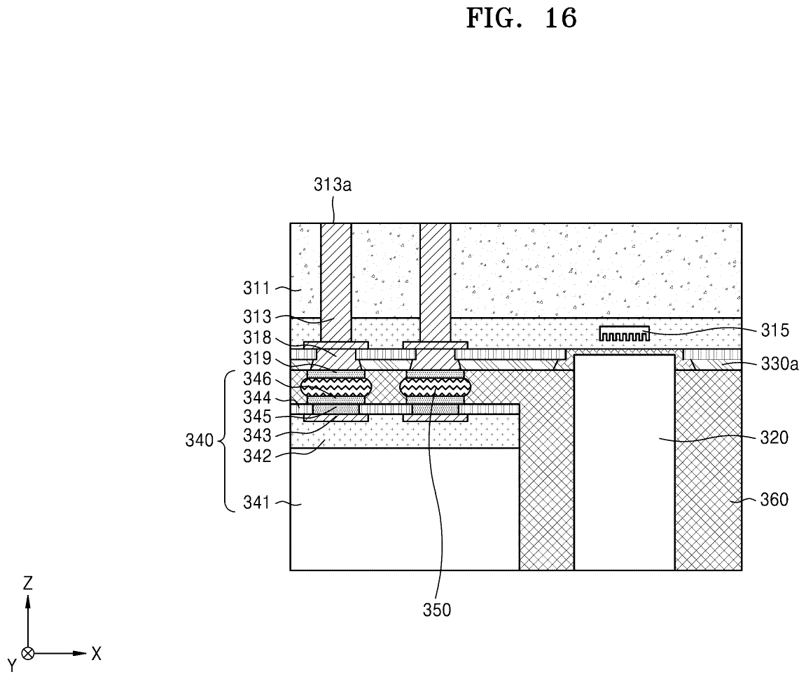

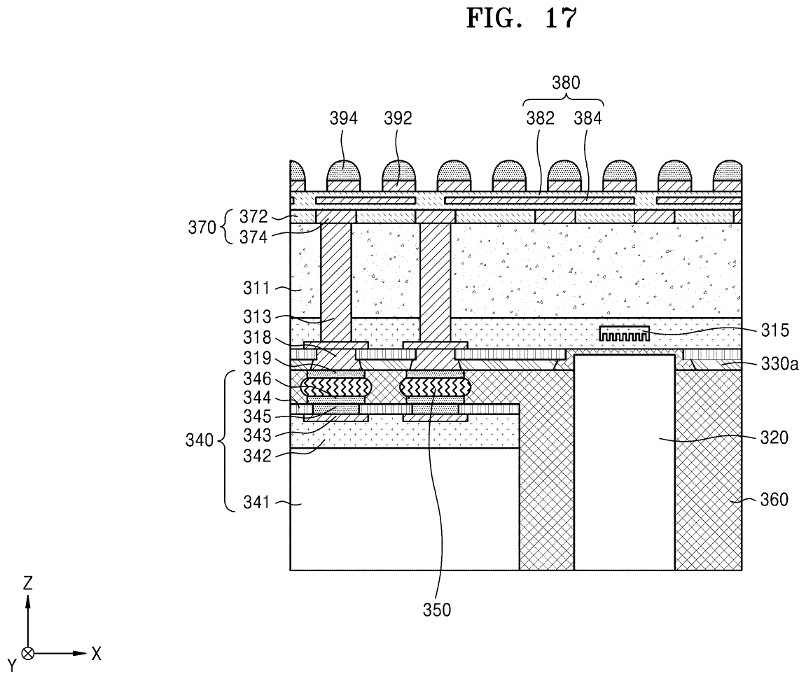

Referring to FIGS. 16 and 17, after the resulting structure of FIG. 15 is turned over, the lower end portion of the first substrate 311 may be removed through a planarization process. By removing the lower end portion of the first substrate 311 through the planarization process, a lower surface 313a (i.e., a surface opposite to the surface facing the electronic integrated circuit chip 340) of the through electrode 313 may be exposed.

Thereafter, a lower connection layer 370 and a redistribution structure 380 may be formed on the resulting structure of FIG. 16. In order to form the lower connection layer 370, an insulating material may be first formed on the first substrate 311 by using a deposition process. The deposition process may include at least one from among a physical vapor deposition (PVD) process, a chemical vapor deposition (CVD) process, and an atomic layer deposition (ALD) process. The chemical vapor deposition process may include a deposition process such as a plasma enhanced chemical vapor deposition (PVD) or a high density plasma chemical vapor deposition (HDPCVD).

Thereafter, a lower pad 374 buried in the lower insulating layer 372 of the lower connection layer 370 may be formed. The lower pad 374 may be formed through a plating process or the like.

In order to form the redistribution structure 380, an insulating material may be first deposited on the lower insulating layer 372 by using a deposition process. The deposition process may include at least one from among a physical vapor deposition process, a chemical vapor deposition process, and an atomic layer deposition process.

Thereafter, a redistribution pattern layer 384 may be formed on the lower insulating layer 372 through a plating process, and an insulating material may be deposited to form a redistribution insulating layer 382 to bury the redistribution pattern layer 384. This process may be repeated to form the redistribution structure 380.

After forming the redistribution structure 380, a photonic chip pad 392 and a photonic chip bump 394 may be formed over the redistribution structure 380. The photonic chip pad 392 may be formed on an upward surface (with respect to FIG. 17) of the redistribution structure 380. Thereafter, the photonic chip bump 394 may be attached onto the photonic chip pad 392.

While non-limiting example embodiments of the present disclosure have been particularly shown and described with reference to drawings, it will be understood that various changes in form and details may be made therein without departing from the spirit and scope of the present disclosure.

What is claimed is:

1. A photonic chip structure comprising:
an electronic integrated circuit chip;
a connection terminal connected to the electronic integrated circuit chip;
an optical integrated circuit chip under the electronic integrated circuit chip and the connection terminal in a vertical direction and comprising a photonic integrated circuit (PIC) connection pad and a first PIC insulating layer on the PIC connection pad, the PIC connection pad connected to the connection terminal; and
an optical block spaced apart from the electronic integrated circuit chip in a horizontal direction and configured to provide a path for optical signals to the optical integrated circuit chip,
wherein the first PIC insulating layer includes a first cavity, and the optical block is in the first cavity.

2. The photonic chip structure of claim 1, wherein the optical integrated circuit chip further comprises a second PIC insulating layer contacting an upper surface of the first PIC insulating layer and on the PIC connection pad,
wherein the second PIC insulating layer includes a second cavity having a greater width than a width of the first cavity, and the optical block is in the second cavity.

3. The photonic chip structure of claim 2, wherein the first cavity completely overlaps with the second cavity in the vertical direction.

4. The photonic chip structure of claim 1, wherein the optical integrated circuit chip further comprises a second PIC insulating layer contacting an upper surface of the first PIC insulating layer and on the PIC connection pad,
wherein the second PIC insulating layer includes a second cavity having a same width as a width of the first cavity, and the optical block is in the second cavity.

5. The photonic chip structure of claim 1, wherein the optical integrated circuit chip further comprises an adhesive layer on the optical block in the first cavity and on a side surface of the first PIC insulating layer.

6. The photonic chip structure of claim 5, wherein the optical integrated circuit chip further comprises:
a grating coupler configured to accommodate the optical signals; and
an interlayer insulating layer,
wherein the grating coupler is in the interlayer insulating layer, and
wherein a portion of an upper surface of the interlayer insulating layer contacts the adhesive layer.

7. The photonic chip structure of claim 6, wherein the grating coupler overlaps with the optical block in the vertical direction.

8. The photonic chip structure of claim 1, wherein the optical integrated circuit chip further comprises a through electrode connected to the PIC connection pad.

9. The photonic chip structure of claim 1, further comprising a molding layer that surrounds the electronic integrated circuit chip.

10. The photonic chip structure of claim 1, wherein the optical block comprises silicon (Si).

11. A photonic chip structure comprising:
an electronic integrated circuit chip;
a connection terminal connected to the electronic integrated circuit chip;
an optical integrated circuit chip under the electronic integrated circuit chip and the connection terminal in a vertical direction and comprising a through electrode and an interlayer insulating layer on at least a portion of the through electrode, the through electrode connected to the connection terminal;
an optical block spaced apart from the electronic integrated circuit chip in a horizontal direction and configured to provide a path for optical signals to the optical integrated circuit chip; and
an adhesive layer directly contacting the optical block and the interlayer insulating layer.

12. The photonic chip structure of claim 11, wherein the adhesive layer is on at least a portion of a side surface of the optical block.

13. The photonic chip structure of claim 11, wherein the optical integrated circuit chip further comprises a grating coupler in the interlayer insulating layer and overlapping with the optical block in the vertical direction.

14. The photonic chip structure of claim 11, wherein the optical integrated circuit chip further comprises:
a first photonic integrated circuit (PIC) insulating layer extending along an upper surface of the interlayer insulating layer and including a first cavity that accommodates the optical block; and
a second PIC insulating layer extending along an upper surface of the first PIC insulating layer and including a second cavity, that accommodates the optical block and overlaps with the first cavity.

15. The photonic chip structure of claim 14, wherein a width of the second cavity is greater than a width of the first cavity.

16. The photonic chip structure of claim 14, wherein a vertical level of an uppermost surface of the adhesive layer is higher than a vertical level of an uppermost surface of the second PIC insulating layer.

17. The photonic chip structure of claim 11, wherein the through electrode does not overlap with the optical block in the vertical direction.

18. The photonic chip structure of claim 11, wherein the interlayer insulating layer comprises silicon oxide.

19. A semiconductor package comprising:
a package substrate;
an interposer above the package substrate;
a memory chip structure above the interposer;
a non-memory chip structure above the interposer and spaced apart from the memory chip structure in a horizontal direction; and
a photonic chip structure spaced apart from the non-memory chip structure in the horizontal direction with the non-memory chip structure therebetween,
wherein the photonic chip structure comprises:
an electronic integrated circuit chip;
a connection terminal connected to the electronic integrated circuit chip;
an optical integrated circuit chip under the electronic integrated circuit chip and the connection terminal in a vertical direction and comprising a photonic integrated circuit (PIC) connection pad and a PIC insulating layer on the PIC connection pad, the PIC connection pad electrically connected to the connection terminal; and
an optical block spaced apart from the electronic integrated circuit chip in the horizontal direction and configured to provide a path for optical signals to the optical integrated circuit chip, and
wherein the PIC insulating layer includes a cavity, and the optical block is in the cavity.

20. The semiconductor package of claim 19, wherein a thickness of the optical integrated circuit chip is 10 micrometers to 200 micrometers in the vertical direction,
wherein a thickness of the electronic integrated circuit chip is 550 micrometers to 750 micrometers in the vertical direction, and
wherein the PIC insulating layer comprises silicon nitride.
